(19) United States
(12) Patent Application Publication
(10) Pub. No.: US 2017/0186807 A1
(43) Pub. Date: Jun. 29, 2017

(54) MODULAR IMAGING DETECTOR ASIC

(71) Applicant: KONINKLIJKE PHILIPS N.V., EINDHOVEN (NL)

(72) Inventors: Marc Anthony Chappo, ELYRIA, OH (US); Rafael GOSHEN, HAIFA (IL)

(73) Assignee: KONINKLIJKE PHILIPS N.V., EINDHOVEN (NL)

(21) Appl. No.: 15/316,533

(22) PCT Filed: May 19, 2015
(86) PCT No.: PCT/IB2015/053665

§ 371 Date: Dec. 6, 2016

Related U.S. Application Data
(60) Provisional application No. 62/009,974, filed on Jun. 10, 2014.

(51) Int. Cl. H01L 27/146; G01T 1/20

(52) U.S. Cl. CPC H01L 27/14663; H01L 27/14661; H01L 27/14658; G01T 1/2018; H01L 27/1469; H01L 27/14687; H01L 27/146

(57) ABSTRACT

An imaging system detector array (112) includes a detector tile (116). The detector tile includes a photosensor array (202), including a plurality of photosensor pixels (204). The detector tile further includes a scintillator array (212) optically coupled to the photosensor array. The detector tile further includes an electronics layer or ASIC on a substrate (214) that is electrically coupled to the photosensor array. The electronics layer includes a plurality of individual and divisible processing regions (302). Each processing region including a predetermined number of channels corresponding to a sub-set of the plurality of photosensor pixels. The processing regions are in electrical communication with each other. Each processing region includes its own electrical reference and bias circuitry (802, 804).

The following generally relates to imaging and more particularly to an imaging detector that includes at least a sub-portion of a modular imaging detector application specific integrated circuit (ASIC), and is described with particular application to computed tomography (CT). However, the following is also amenable to other imaging modalities.

A computed tomography (CT) scanner includes an x-ray tube mounted on a rotatable gantry that rotates around an examination region about a longitudinal or z-axis. The x-ray tube emits ionizing radiation that traverses the examination region and a subject or object therein. A detector array subtends an angular arc opposite the examination region from the x-ray tube. The detector array detects radiation that traverses the examination region and generates a signal indicative thereof. A reconstructor processes the signal and reconstructs volumetric image data indicative of the examination region. The reconstructed volumetric image can be further processed to generate one or more images of the examination region.

The detector array has included an integrating detector with a scintillator array optically coupled and mounted to one side of a photosensor array and an ASIC mounted to an opposing side of the photosensor array. The ASIC includes channels that are in electrical communication with electrical contacts to the photosensitive pixels. For example, a detector with a photosensor array with 64 photosensitive pixels has an ASIC with 64 corresponding channels. Generally, the ASIC is optimized for the specific numbers of pixels with, for example, 64, 128, 256 or 512 channels. However, this limits the applicability of an ASIC to a particular product line. For example, an ASIC optimized for 64 channels, generally, is limited to an imaging system with a detector array with a photosensor array with 64 photosensor pixels.

As a consequence, multiple different detector configurations (e.g., 64, 128, 256, 512, etc. photosensitive pixels) for different imaging system configurations require corresponding multiple different optimized ASICs (e.g., 64, 128, 256, 512, etc. channels). Unfortunately, this leads to manufacturing inefficiencies. For example, development of a specific ASIC may take two 2 years with each costing in excess of one million dollars, and each ASIC is characterized and qualified with special test equipment. In another example, an ASIC (which is optimized for a 128 photosensitive pixel detector) that has improperly functioning channels at testing would be discarded, lowering the overall yield. An approach for overcoming some of the inefficiencies is to just use higher end ASICs (e.g., 512 channels) for all imaging system configurations. Unfortunately, this may be size and cost prohibitive for lower (e.g., less than 512 photosensor pixel) end imaging systems.

Aspects described herein address the above-referenced problems and others.

The following describes a single modular ASIC, which is divisible into one or more fully functional reduced channel ASICs that can be used in different detector configurations (e.g., 1, 2, 4, 8, 16, 32, 64, 128, 256, 512, 1024, etc. pixels). With this approach, an ASIC with a larger number of channels (e.g. 512 or more channels) can be fabricated (e.g., with a small feature size of 0.05 micron to 0.20 micron) and tested, and then used in a high definition detector or physically divided to produce one or more reduced channel ASICs (e.g., 64 channel) for a lower definition or lower pixel count detector. As a result, ASICs with a different number of channels can be produced from a single fabrication, optimizing both cost and size across the different detector configurations.

In one aspect, an imaging system detector array includes a detector tile. The detector tile includes a photosensor array, including a plurality of photosensor pixels. The detector tile further includes a scintillator array optically coupled to the photosensor array. The detector tile further includes an electronics layer that is electrically coupled to the photosensor array. The electronics layer includes a plurality of individual processing regions. Each processing region includes a predetermined number of channels corresponding to a sub-set of the plurality of photosensor pixels. The processing regions are in electrical communication with each other. Each processing region includes its own electrical reference and bias circuitry.

In another aspect, a method includes fabricating and testing an ASIC that includes a first number of processing regions. Each processing region includes a predetermined number of channels. Each processing region includes its own electrical reference and bias circuitry. The method further includes dicing the ASIC into at least two fully functional reduced channel ASICS respectively having a second and a third number of channels. The second and the third number of channels is less that the first number of channels. The method further includes employing at least one of the at least two fully functional reduced channel ASICS in a detector array of an imaging system.

In another aspect, an ASIC for an imaging detector tile includes a plurality of individual processing regions, each processing region including a predetermined number of channels corresponding to a sub-set of a plurality of photosensor pixels of the detector tile, wherein the processing regions are in electrical communication with each other, and each processing region includes its own electrical reference and bias circuitry.

The invention may take form in various components and arrangements of components, and in various steps and arrangements of steps. The drawings are only for purposes of illustrating the preferred embodiments and are not to be construed as limiting the invention.

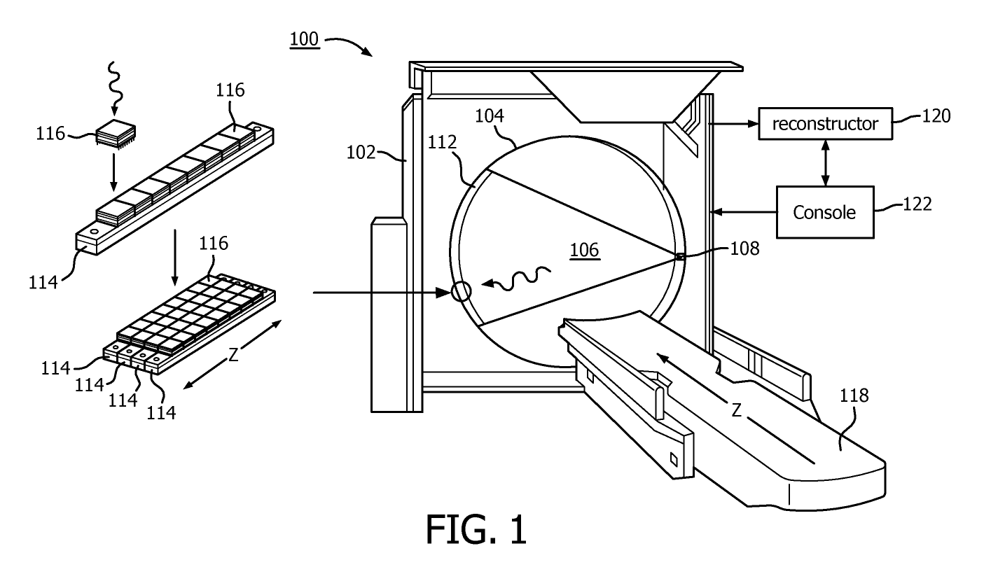

FIG. 1 schematically illustrates an example imaging system with a detector array that includes at least a sub-portion of a single modular ASIC that is divisible into one or more fully functional reduced channel ASICs.

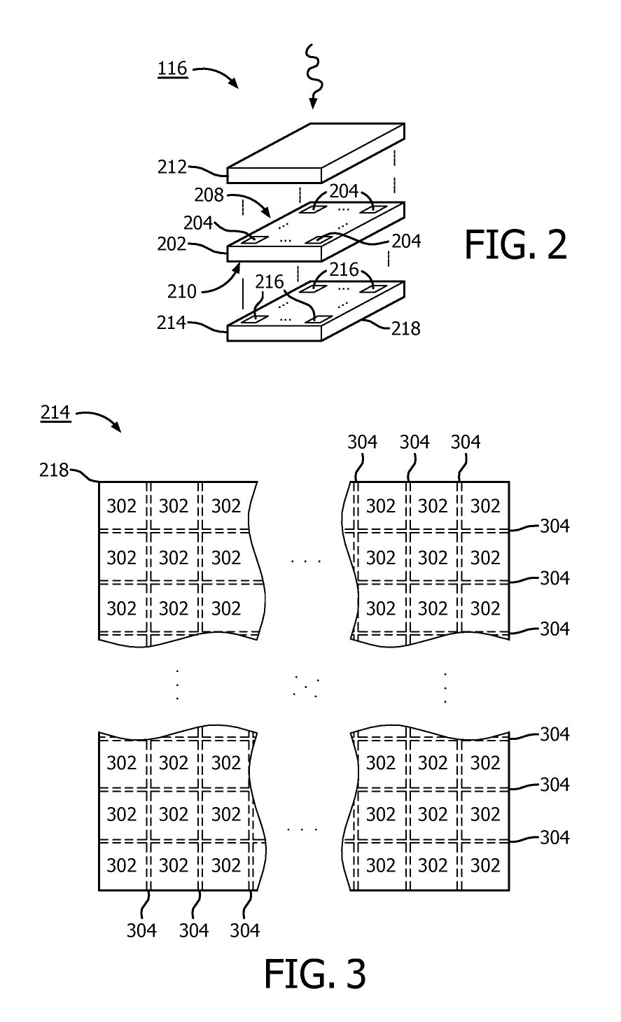

FIG. 2 schematically illustrates an example detector tile that includes the single modular ASIC.

FIG. 3 schematically illustrates an example of the single modular ASIC with M×N processing regions.

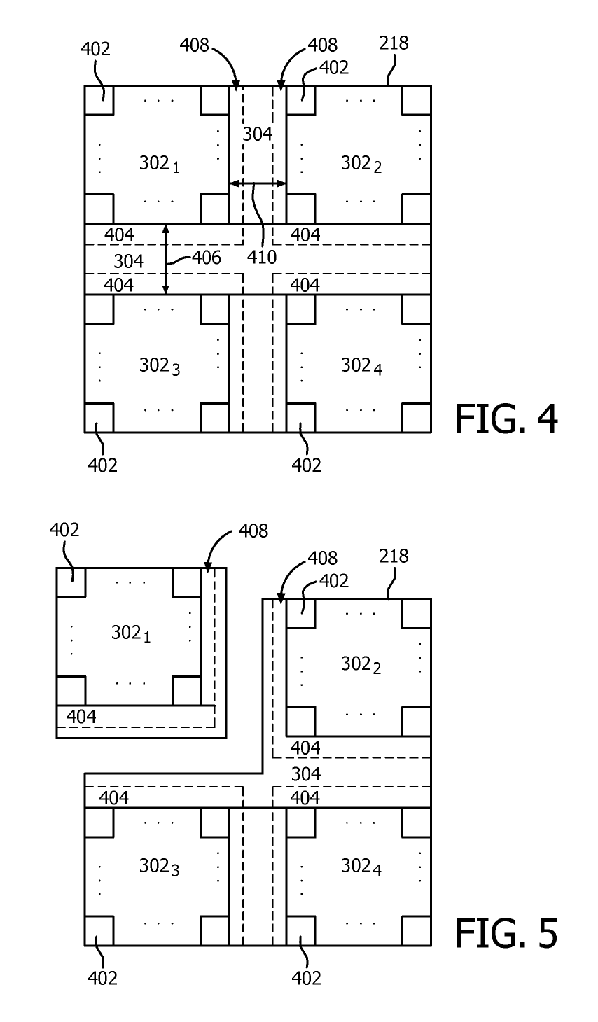

FIG. 4 schematically illustrates an example of the single modular ASIC with four (M=N=2, or 2×2) processing regions and digital and analog regions.

FIG. 5 schematically illustrates an example of dicing a reduced channel ASIC from the single modular ASIC of FIG. 4.

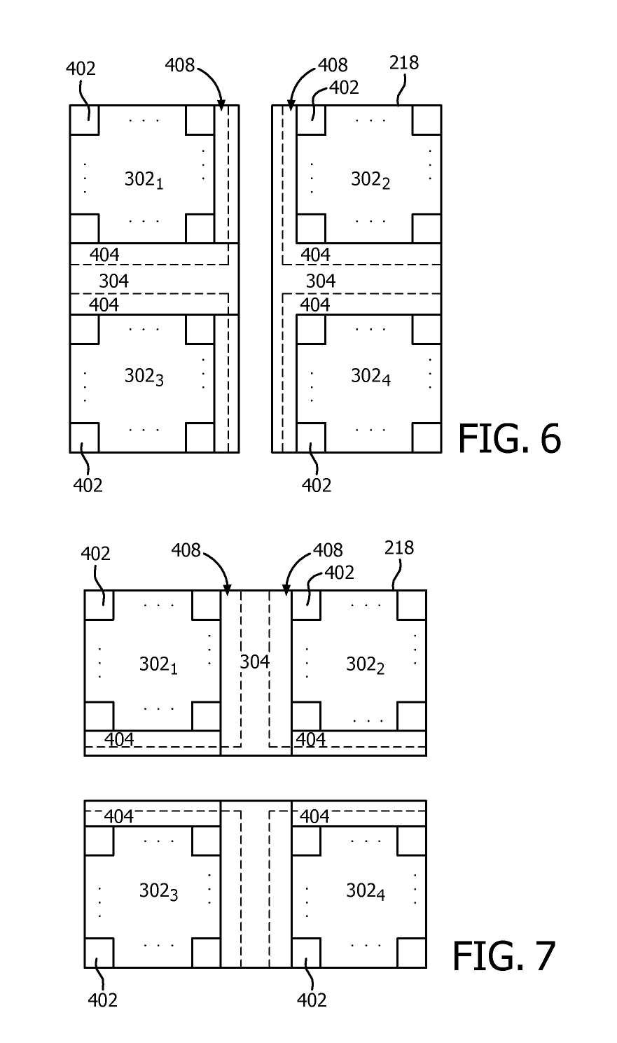

FIG. 6 schematically illustrates another example of dicing a reduced channel ASIC from the single modular ASIC of FIG. 4.

FIG. 7 schematically illustrates still another example of dicing a reduced channel ASIC from the single modular ASIC of FIG. 4.

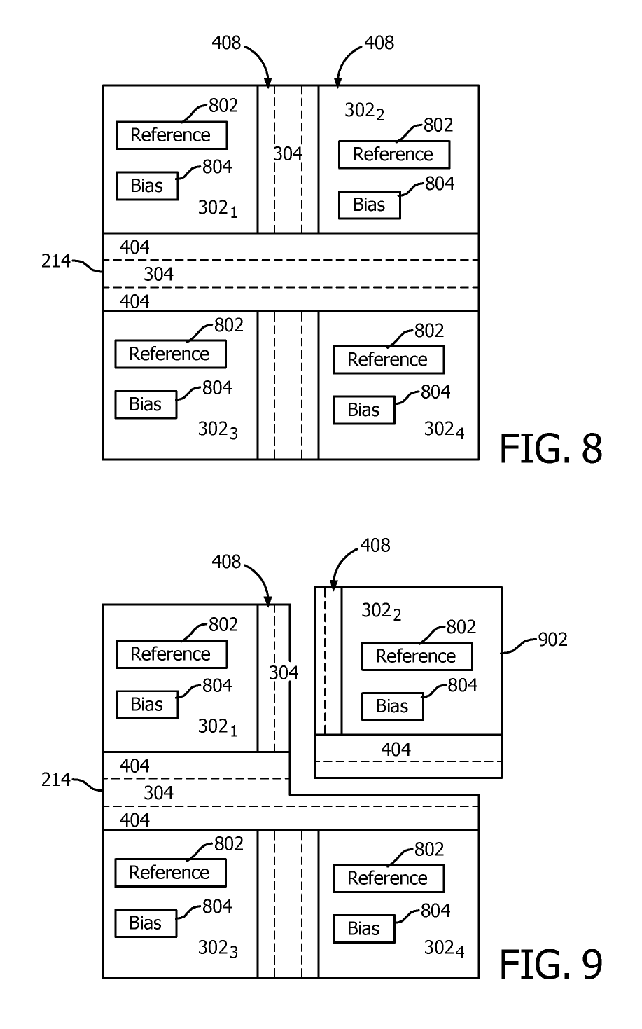

FIG. 8 schematically illustrates an example of the ASIC in which each processing region includes its own internal reference and bias circuitry.

FIG. 9 schematically illustrates the ASIC in FIG. 8 in which the ASIC is diced.

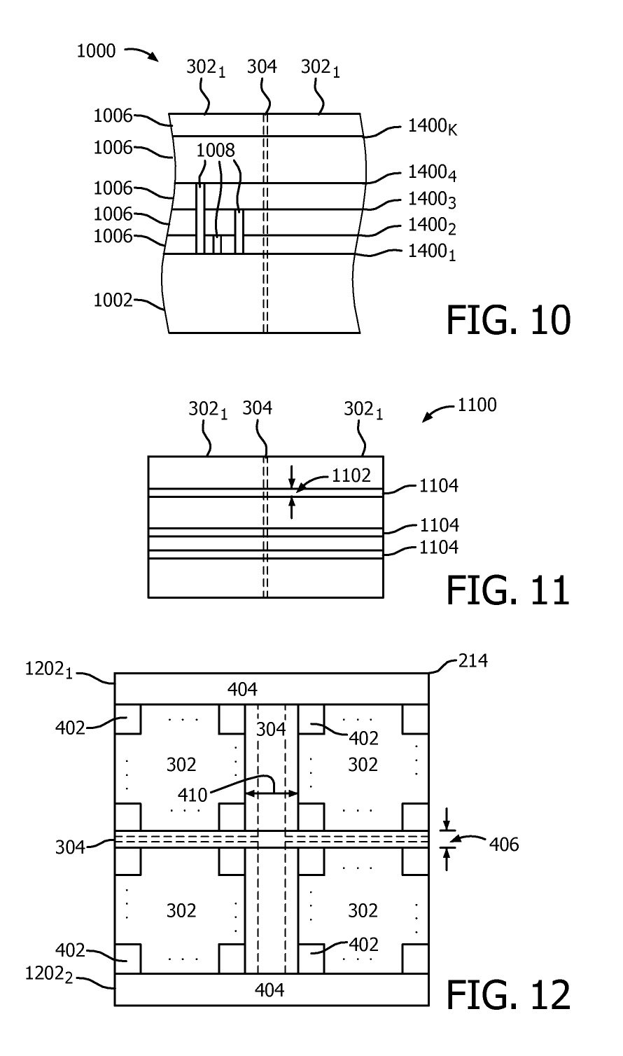

FIG. 10 schematically illustrates a side view of the ASIC, showing metal layers of the ASIC.

FIG. 11 schematically illustrate a top down view of the ASIC, showing electrical connections across processing regions of the ASIC.

FIG. 12 schematically illustrates a variation of FIG. 4 in which the processing regions are located between the digital regions.

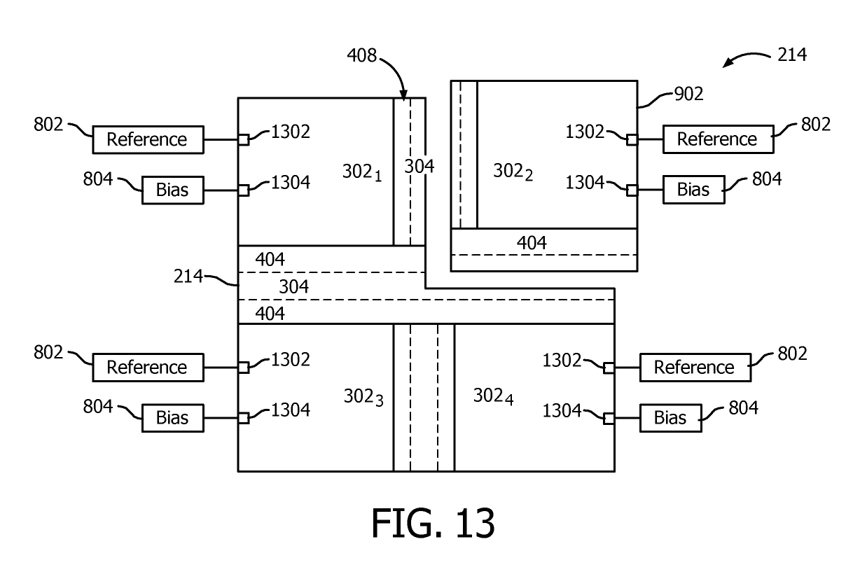

FIG. 13 schematically illustrates a variation of FIG. 8 in which the reference and bias circuitry is external to the processing regions.

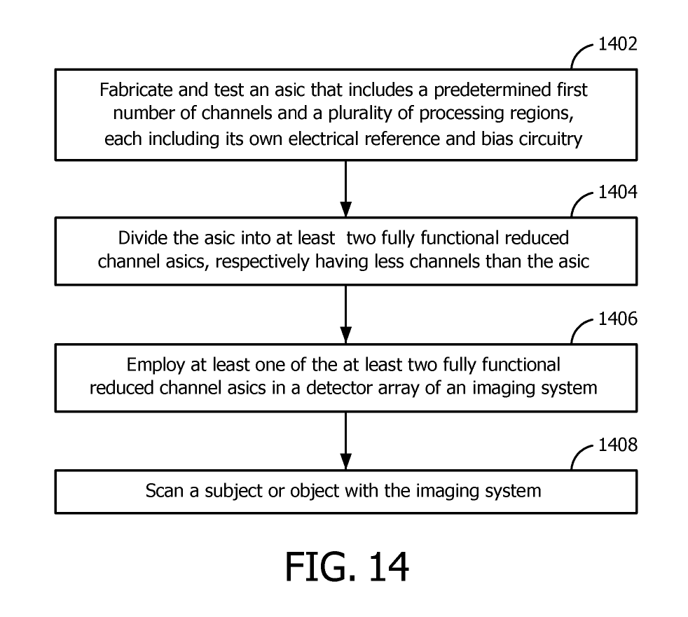

FIG. 14 illustrates a method in accordance with the system described herein.

FIG. 1 illustrates an imaging system 100 such as a computed tomography

(CT) scanner. The imaging system 100 includes a generally stationary gantry 102 and a rotating gantry 104. The rotating gantry 104 is rotatably supported by the stationary gantry 102 and rotates around an examination region 106 about a longitudinal or z-axis. A radiation source 108 such as an x-ray tube is supported by and rotates with the rotating gantry 104 and emits radiation that traverses the examination region 106.

A radiation sensitive detector array 112 subtends an angular arc opposite the radiation source(s) 108 across the examination region 106 and detects radiation traversing the examination region 106. The radiation sensitive detector array 112 includes a plurality of detector modules 114 arranged with respect to each other along a direction transverse to the z-axis. A detector module 114 includes a plurality of detector mosaics or tiles 116 arranged with respect to each other along the z-axis. A non-limiting example of such a detector array is described in U.S. Pat. No. 6,510,195B1, filed Jul. 18, 2001, and entitled “Solid State X-Radiation Detector Modules and Mosaics thereof, and an Imaging Method and Apparatus Employing the Same,” which is incorporated herein by reference in its entirety.

Briefly turning to FIG. 2, an example of a detector tile 116 is schematically illustrated. The detector tile 116 is an integrating detector, including a photosensor layer 202, which includes a plurality of photosensitive pixels 204 on a first side 208. The illustrated photosensor layer 202 is back-illuminated with electrodes (not visible) that inter-connect the photosensitive pixels 204 to bonding pads or the like (not visible) located on a second opposing side 210 of the photosensor 202. In a variation, the photosensor 202 can be a front-illuminated photosensor with vias (including but not limited to through silicon vias, TSVs) that route the signals from the first side 208 to the pads on the opposing side 210. In another variation, the detector tile 116 can be a multi-layer, spectral (multi-energy) detector tile with multiple scintillator/photosensor pairs, each of which is sensitive to a different photon energy range.

The detector tile 116 further includes a scintillator layer 212. The scintillator layer 212 may be a single layer or include a plurality of scintillator pixels (pixelated). In the latter instance, the scintillator layer 212 may include a number of scintillator pixels corresponding to a number of photosensitive areas for a one to one relationship between scintillator pixel and photosensitive area 204. In yet another instance, different scintillator pixels may correspond to different sub-groups of the photosensitive areas 204. The scintillator layer 212 is optically coupled to the photosensor 202.

The detector tile 116 further includes an electronics layer (e.g., an ASIC) 214 with electrically conductive pads 216 that couple with the bonding pads of the photosensitive pixels 204. The ASIC or ASIC on a substrate 214 includes a channel for each of the photosensitive pixels 204, along with digital and analog circuitry. Such circuitry includes an A/D converter, which is implemented as a current-to-frequency (I/F) converter that generates a train of pulses with a pulse frequency indicative of x-ray photons incident on a detector pixel. Examples of such a converter are described in U.S. Pat. No. 6,671,345 B2 Vrettos et al., filed Nov. 7, 2001, and entitled “Data Acquisition for Computed Tomography,” which is incorporated herein by reference in its entirety, and “A New 2D-Tiled Detector for Multislice CT,” Luhta et al., Medical Imaging 2006: Physics of Medical Imaging, Vol. 6142, pp. 275-286 (2006).

The illustrated ASIC or ASIC on a substrate 214 is a modular ASIC, with a single unitary die 218 that is divisible into one or more reduced channel ASICs that can be used in different detector configurations (e.g., 1, 2, 8, 16, 32, 64, 128, 256, 512, 1024, etc. photosensitive pixels). The single unitary die 218 may include at least one of a flex, a ceramic, a silicon, etc. material, a print circuit board (PCB), etc. As described in greater detail below, the single unitary die 218 is populated with electronics such that the individual reduced-channel ASICs include suitable electronics to be fully functional reduced channel ASICs. As such, manufacturing inefficiencies can be mitigated by fabricating and testing a single modular ASIC 218, and producing desired channel size ASICs 218 therefrom, without introducing size and cost prohibitive constraints on lower end systems.

This approach may also improve yields as an ASIC 218 that has improperly functioning channels can be diced to produce a reduced channel ASIC with properly functioning channels, instead of discarding the entire ASIC or ASIC on a substrate 214. Generally, the number of ASIC channels should fit the number of detection channels so each photodiode will be connected to one preamplifier. If the ASIC has more channels, it will take more power consumption and physical space in an area, which is often already densely populated. In one instance, a particular size ASIC (e.g., 512 channel) is fabricated and qualified, and subsequently used to produce 512 channel or sub units like 256, 128 or 64 channel ASICs. This may result in a direct cost saving and in non-direct cost savings, for example, due to large use of one type of ASIC. The base ASIC will serve many types of detectors, each one with different number of input channels.

Returning to FIG. 1, a patient support 118, such as a couch, supports an object or subject such as a human patient in the examination region 106. The patient support 118 is configured to move the object or subject in and/or out of the examination region 106 before, during and/or after scanning the object or subject. A reconstructor 120 reconstructs the signal from the detector array 112 and generates volumetric image data indicative thereof. The volumetric image data can be further processed to generate one or more images, which can be presented via a display, filmed, or otherwise output.

A general-purpose computing system serves as an operator console 122. The console 122 includes one or more processors that execute one or more computer readable instructions (software) stored or encoded in computer readable storage medium local or remote to the system 100. Software resident on the console 122 allows the operator to control operation of the system 100 initiating scanning, etc. The console 122 also includes an output device such as display and an input device such as a keyboard, mouse, touch screen, etc.

FIG. 3 schematically illustrates an example of the single modular ASIC or ASIC on a substrate 214. The ASIC 218 includes individually and independently fully functioning processing regions 302. Each processing region 302 includes channels that interface with the photosensitive pixels 204 (FIG. 2) and circuitry for processing electrical signals generated by and obtained from the photosensitive pixels 204.

In the illustrated embodiment, the processing regions 302 are separated from each other by dividing regions 304 (which are delineated in FIG. 3 through imaginary dashed lines) that reside within common or shared regions of the ASIC, for example, shared analog and/or digital regions shared across processing regions 302. In FIG. 3, there are N rows and M columns of processing regions 302, where N and M are positive integers

FIG. 4 shows the ASIC 218 of FIG. 3 for N=M =2. In FIG. 4, each of the processing regions 302₁, 302₂, 302₃, and 302₄ includes an array of J channels 402 (where J is a positive integer) and a sub-portion 404 of a common digital region 406 and a sub-portion 408 of a common analog region 410. The dividing regions 304 are within the common digital region 406 and the common analog region 410.

Turning to FIG. 5, one of the processing regions 302 (i.e., processing region 302₁) is shown diced and separated from the single modular ASIC 214. The ASIC 218 die is diced to those skilled in the art of ASIC fabrication, for example, by laser cutting, mechanical sawing, scribing and breaking, and/or other dicing. A small percentage of the ASIC die will be lost due to the dicing, for example, about 150 microns or less. However, the ASIC 218 can be fabricated to take this into account, if needed.

In FIG. 5, the ASIC 218 is diced within the dividing regions 304. The single modular ASIC 218, prior to dicing, included four processing regions 302, each with J channels, providing 4J channels for a 4J photosensor pixel array. The diced processing region 302₁ provides J channels for a J pixel photosensor pixel array. The remainder of the single modular ASIC 218 can be used with a 3J pixel photosensor pixel array or further diced to provide three more J channel ASICs or another J channel ASIC and a 2J channel ASIC.

In FIG. 6, a pair of adjacent processing regions 302 is shown diced from the single modular ASIC 218. In FIG. 6, the ASIC 218 is diced within the dividing region 304 within the common analog circuitry 408 and results in 2J channels for a 2J photosensor pixel array. The remainder of the single modular ASIC 214 can be used with a 2J photosensor pixel array or further diced to provide two J channel ASICS.

In FIG. 7, a different pair of adjacent processing regions 302 is shown diced from the single modular ASIC 218. In FIG. 7, the ASIC 218 is diced within the dividing region 304 within the common digital circuitry 404 and results in 2J channels for a 2J photosensor pixel array. The remainder of the single modular ASIC 218 can be used with a 2J photosensor pixel array or further diced to provide two J channel ASICS.

FIG. 8 schematically illustrates an embodiment of the ASIC 218 in which each of the divisible processing regions 302 includes its own reference circuitry 802 and bias circuitry 804, which in internal to the processing regions 302. As such, the ASIC 218 will include duplicate reference circuitry 802 and bias circuitry 804. With this configuration, dicing the ASIC die, as shown in FIG. 5 (or otherwise) renders a fully functional reduced channel ASICs 902, as shown in FIG. 9.

FIGS. 10 and 11 respectively show side and top down views 1200 and 1300 of two processing regions 302₁ and 302₂ of the ASIC 218. The ASIC 218 includes a die substrate 1202 and a plurality of metallization layers 1004₁, 1004₂, 1004₃, 1004₄, . . . , 1004ₖ (where k is a positive integer), collectively referred to as of metallization layers 1004. Passivation layers 1006 are between the metallization layers.

Vias 1008 provides paths for electrical connections between the metallization layers 1004 and the substrate 1002. Electrical paths 1004 cross the dividing regions 304. Generally, the separation between the metallization layers 1004 and widths 1102 of electrical paths 1104 that cross between the two processing regions 302₁ and 320₂ are appropriately sized so that the dicing does not render the electrical connections at the edges non-functional.

FIG. 12 shows a variation of the ASIC 218 of FIG. 4 in which the processing regions 302 are located between (i.e., sandwiched by) first and second sub-portions 1202₁ and 1202₂ of the digital region 406, instead of the digital circuitry 406 being between (i.e., sandwich by) the processing regions 302.

FIG. 13 schematically illustrates a variation of FIG. 8 in which the reference circuitry 802 and bias circuitry 804 are external to the processing regions 302. Each of the processing regions 302 includes electrical contacts 1302 and 1304 for the external the reference circuitry 802 and the bias circuitry 804. In another variation, at least one the reference circuitry 802 or bias circuitry 804 for a processing region 302 is internal to the processing region 302 (FIG. 8) and at least one the reference circuitry 802 or bias circuitry 804 for a processing region 302 is external to the processing region 302 (FIG. 13).

FIG. 14 illustrates an example method in accordance with the description herein.

It is to be appreciated that the ordering of the acts in the methods described herein is not limiting. As such, other orderings are contemplated herein. In addition, one or more acts may be omitted and/or one or more additional acts may be included.

At 1402, an ASIC, including a predetermined first number of channels and a plurality of processing regions, each including its own electrical reference and bias circuitry, is fabricated and tested. As discussed herein, the ASIC is a single modular ASIC, with a single unitary die that is divisible into one or more reduced channel ASICs.

At 1404, the ASIC is divided into at least two fully functional reduced channel ASICS, respectively having a second and a third number of channels, wherein the second and the third number of channels is less that the first number of channels.

At 1406, the at least one of the at least two fully functional reduced channel ASICS are employed in a detector array of an imaging system.

At 1408, a subject or object is scanned with the imaging system.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. An imaging system detector array comprising:
a detector tile including:
a photosensor array including a plurality of photosensor pixels
a scintillator array optically coupled to the photosensor array; and
an electronics layer electrically coupled to the photosensor array, the electronics layer, including: a plurality of individual processing regions each processing region including a predetermined number of channels corresponding to a sub-set of the plurality of photosensor pixels, wherein the processing regions are in electrical communication with each other, and each processing region includes its own electrical reference and bias circuitry.

2. The imaging system detector array of claim 1, wherein the electronics layer is a sub-portion of a single unitary die that includes a plurality of the electronics layers.

3. The imaging system detector array of claim 2, the electronics layer, further including:
a sub-portion of a digital electronics region shared by at least two adjacent electronics layers of the plurality of the electronics layers of the single unitary die.

4. The imaging system detector array of claim 3, wherein the digital electronics region resides between at least two of the processing regions.

5. The imaging system detector array of claim 4, the digital electronics region, comprising: a first sub-portion and a second sub-portion, wherein the processing region resides between the first sub-portion and the second sub-portion of the digital electronics region.

6. The imaging system detector array of claim 2, the electronics layer, further including:
a sub-portion of an analog electronics region shared by at least two adjacent electronics layers of the plurality of the electronics layers of the single unitary die.

7. The imaging system detector array of claim 2, wherein the single die includes 512 channels and the electronics layer of the detector tile includes less than 512 channels.

8. The imaging system detector array of claim 2, wherein the electronics layer of the detector tile includes a first number of channels, wherein the first number of channels is from a group consisting of 16, 32, 64, 128, or 256 channels, and the single die includes a second number of channels, wherein the second number of channels is greater than the first number of channels.

9. The imaging system detector array of claim 1, wherein the electrical reference and bias circuitry of one of the processing regions is internal to the one of the processing regions.

10. The imaging system detector array of claim 1, wherein the electrical reference and bias circuitry of one of the processing regions is external to the one of the processing regions.

11. The imaging system detector array of claim 1, wherein the electronics layer is a sub-portion of a fabricated die having both functional and non-functional channels, wherein the electronics layer includes the functional channels and does not include the non-functional channels of the fabricated die.

12. The imaging system detector array of claim 1, the electronics layer, further comprising:
a current-to-frequency converter that generates a train of pulses with a pulse frequency indicative of x-ray photons incident on a photosensor pixel.

13. The imaging system detector array of claim 1, the electronics layer, further comprising:
at least one of a flex material, a ceramic material, a silicon material, or a print circuit board.

14. A method, comprising:
fabricating and testing an ASIC that includes a first number of processing regions, each processing region including a predetermined number of channels and each processing region including its own electrical reference and bias circuitry;
dicing the ASIC into at least two fully functional reduced channel ASICS respectively having a second and a third number of channels, wherein the second and the third number of channels is less than the first number of channels; and
employing at least one of the at least two fully functional reduced channel ASICS in a detector array of an imaging system.

15. The method of claim 14, further comprising:
dicing the ASIC with one of a laser, a mechanical saw, or a scribe.

16. The method of claim 14, wherein the dicing removes an amount of a material of the ASIC, wherein the amount is in a range of 150 microns or less.

17. The method of claim 14, wherein the at least two fully functional reduced channel ASICS include at least one of a sub-portion of a digital electronics region shared by the at least two fully functional reduced channel ASICS prior to dicing or a sub-portion of a digital electronics region shared by the at least two fully functional reduced channel ASICS prior to dicing.

18. The method of claim 14, wherein the ASIC includes 512 channels and the at least two fully functional reduced channel ASICS include less than 512 channels.

19. The method of claim 14, wherein the at least two fully functional reduced channel ASICS respectively include a first number of channels and a second number of channels, and the ASIC includes a third number of channels, wherein the third number of channels is greater than the first and second number of channels.

20. An ASIC for an imaging detector tile, comprising:
a plurality of individual processing regions, each processing region including a predetermined number of channels corresponding to a sub-set of a plurality of photosensor pixels of the detector tile, wherein the processing regions are in electrical communication with each other, and each processing region includes its own electrical reference and bias circuitry.

21. The ASIC of claim 20, wherein each of the plurality of individual processing regions is a sub-portion of a single unitary die.

22. The ASIC of claim 21, further including:
a digital electronics region shared by at least two of the plurality of individual processing regions.

23. The ASIC of claim 21, further including:
an analog electronics region shared by at least two of the plurality of individual processing regions.

24. The ASIC of claim 21, wherein the single die includes 512 channels and the plurality of individual processing regions includes less than 512 channels.

25. The ASIC of claim 21, wherein the plurality of individual processing regions includes a first number of channels, wherein the first number of channels is from a group consisting of 16, 32, 64, 128, or 256 channels, and the single die includes a second number of channels, wherein the second number of channels is greater than the first number of channels.

26. The ASIC of claim 20, wherein the electrical reference and bias circuitry of one of the plurality of individual processing regions is internal to the one of the plurality of individual processing regions.

27. The ASIC of claim 20, wherein the electrical reference and bias circuitry of one of the plurality of individual processing regions is external to the one of the plurality of individual processing regions.

28. The ASIC of claim 20, wherein the plurality of individual processing regions is divisible into one or more fully functional reduced channel ASICs.

29. The ASIC of claim 28, wherein the plurality of individual processing regions are part of a first definition or first pixel count detector and is divisible into one or more second definition or second pixel count detectors, wherein the first definition is greater than the second definition or the first pixel count is greater than the second pixel count.

30. The ASIC of claim 20, further comprising: at least one feature with a size in a range of 0.05 micron to 0.20 micron.

31. The ASIC of claim 20, further comprising:
a current-to-frequency converter that generates a train of pulses with a pulse frequency indicative of x-ray photons incident on a photosensor pixel.
